(19) United States
(12) Patent Application Publication
(10) Pub. No.: US 2005/0051209 A1
(43) Pub. Date: Mar. 10, 2005

(54) System and method for implementing virtual solar cell

(75) Inventor: Gyu Ha Choe, Seoul (KR)

Correspondence Address: GREENBLUM & BERNSTEIN, P.L.C., 1950 ROLAND CLARKE PLACE, RESTON, VA, 20191, US

(73) Assignee: KONKUK UNIVERSITY, Seoul (KR)

(21) Appl. No.: 10/724,616

(22) Filed: Dec. 2, 2003

(30) Foreign Application Priority Data
Sep. 4, 2003 (KR) 2003-61685

(51) Int. Cl. H01L 31/00

(52) U.S. Cl. 136/293; 136/252

(57) ABSTRACT

There is disclosed a system for implementing a virtual solar cell, which virtually produces output characteristic of a solar cell that satisfies conditions such as insolation, temperature and so on, to embody the performance of a solar cell without having an actual solar cell array. The system includes a data detector, a controller, a power converter, and a data logging unit, to measure external environment information such as temperature, insolation and wind velocity, and solar cell output characteristic according thereto to construct a database. In the case that output characteristic of a solar cell installed in the place a user desires at the time a user wants is produced when an actual solar developing system is designed, the system of the invention generates a voltage-current model of the solar cell, suitable for that situation, to obtain the same input/output characteristics of the solar cell as those of an actual solar cell. Furthermore, the data logging system of the present invention can store various characteristics of solar cells, generated and controlled by the controller, and interface with a user using the stored characteristics to perform remote control.

### BACKGROUND OF THE INVENTION

1. Field of the Invention

The present invention relates to a solar power generation system and, more particularly, to a system and method for implementing a virtual solar cell to obtain the same output power characteristic as that of a solar cell located in the place a user wants at the time when the user desires even without installing an actual solar cell array in the spot.

2. Background of the Related Art

In general, a solar cell means a photoelectric cell that converts solar energy into electrical energy. This solar cell is usually used for a solar power generator that changes optical energy into electrical energy to charge the electrical energy in a condenser and processes the charged electrical energy to supply it to a load. The solar power generation becomes the center of interests as a clean power generating method because it does not create environmental problems including nuclear contamination and global warming and produces high power generation efficiency with relatively simple installations. Accordingly, a variety of researches and developments for practical use of the solar cell are being carried out.

FIG. 1 shows the construction of an electrical power generation circuit of a conventional solar cell. The electrical power generation circuit includes a solar cell array 1, a power regulator 2 and a load 3. The solar cell array 1 has a temperature sensor 4 in order to obtain the maximum output power from solar cells. The temperature sensor 4 detects a temperature variation of the solar cell array 1. A temperature measurer 5 measures the temperature variation detected by the temperature sensor. A maximum voltage setting unit 6 controls the power regulator 2 to obtain the maximum output voltage in the measured temperature.

The power generation circuit of the conventional solar cell has relatively simple construction so that the circuit is easy to construct. However, it is very difficult to design a system capable of obtaining the maximum output power because temperature, insolation, characteristics of solar cells by manufacturers and other external environments vary at all times. To solve this problem, system designers install solar cell arrays in a wide space and perform repeated experiments using information such as voltage and current outputted from the arrays to design the optimum system.

However, this designing method requires a wide space for installing the solar cell arrays and an enormous cost for purchasing the solar cell arrays. Furthermore, it is impossible to execute the repeated experiments under a specific condition because the output power of the solar power generation system remarkably varies with insolation, temperature and so on. Accordingly, it is very difficult to make experimental approaches to the solar power generation system. Especially, there are many difficulties in designing the optimum power converting circuit capable of generating maximum efficiency.

To solve these problems, an apparatus for constructing an analogue solar cell system using a linear regulator has been proposed. However, this solar cell system using the linear regulator cannot perform accurate power control in the event of power conversion because its controller for controlling power is constructed of an analog circuit. In addition, output efficiency of solar cells is poor because conditions such as insolation, temperature and so on sensitively vary with surrounding environments. Especially, output power control in a wide range is impossible because the output power of the solar cells is regulated by the linear regulator.

Meanwhile, there has been disclosed an apparatus that controls luminous intensity of lights irradiated to a solar cell to reproduce a condition of solar radiation according to insolation or temperature in order to control characteristic of the conventional solar cell system. However, this solar cell characteristic controlling apparatus has been developed as an apparatus for testing the solar cell according to the condition of solar radiation so that it cannot be an alternative to an actual solar cell. Moreover, since the apparatus tests the solar cells using existing solar cell arrays, there is a limitation in the cost and area required for installing the solar cell arrays.

### SUMMARY OF THE INVENTION

Accordingly the present invention has been made to solve the above problems, and an object of the present invention is to provide a virtual solar cell having the same electrical characteristic as the output power characteristic of an actual solar cell depending on conditions such as insolation, temperature and so on without having an actual solar cell array.

Another object of the present invention is to provide a system and method for implementing a virtual solar cell, capable of carrying repeated experiments under the same environmental condition by using a database constructed of insolation, temperature, wind velocity, output characteristics of solar cells by manufacturers and experimental results.

Yet another object of the present invention is to provide a system and method for implementing a virtual solar cell to model a voltage-current control algorithm the most suitable for an actual solar cell using output power characteristic of the virtual solar cell and apply the voltage-current control algorithm to an actual system.

To accomplish the above objects, according to one aspect of the present invention, there is provided a system for implementing a virtual solar cell, comprising: a data detector including a measurement sensor and adapted to collect external environment data; a controller for receiving real-time data from the data detector, classifying the received data in a predetermined format to transmit the classified data to a data logging unit, generating a voltage-current model having the same effect as that of an actual solar cell on the basis of the received data, and generating a pulse width modulation signal for controlling a power converter according to the model; the power converter for converting input power in response to the pulse width modulation signal to provide power to a load; and the data logging unit for communicating with the controller or the data detector according to a predetermined communication method, and storing data received from the controller or the data detector.

To accomplish the above objects, according to another aspect of the present invention, there is also provided a method for implementing a virtual solar cell, comprising: allowing a controller to receive data from the outside; classifying the received data in a predetermined format or stores it; generating a voltage-current model for obtaining output characteristic of an actual solar cell on the basis of the received data; performing current control according to the generated model; generating a pulse width modulation signal according to a result of the current control; and controlling a power converter in response to the pulse width modulation signal.

It is to be understood that both the foregoing general description and the following detailed description of the present invention are exemplary and explanatory and are intended to provide further explanation of the invention as claimed.

### BRIEF DESCRIPTION OF THE DRAWINGS

The above and other objects, features and other advantages of the present invention will be more apparent from the following detailed description of the preferred embodiments of the invention in conjunction with the accompanying drawings, in which:

FIG. 1 is a block diagram of a power generation circuit of a conventional solar cell;

FIG. 2 illustrates the construction of a system for implementing a virtual solar cell according to the present invention;

FIGS. 3a and 3b illustrate the composition of pictures showing an embodiment of generating a voltage-current model of a solar cell according to an embodiment of the present invention;

FIG. 4 illustrates the composition of a picture of a data logging unit according to an embodiment of the present invention;

FIG. 5 illustrates the composition of a current controller according to the present invention;

FIG. 6 is a circuit diagram of a power converter according to the present invention;

FIG. 7 illustrates an equivalent circuit of a reactor output terminal of the power converter according to the present invention;

FIG. 8 illustrates an over-current profile of the power converter according to the present invention; and

FIG. 9 is a flow chart showing a procedure of implementing a virtual solar cell according to the present invention.

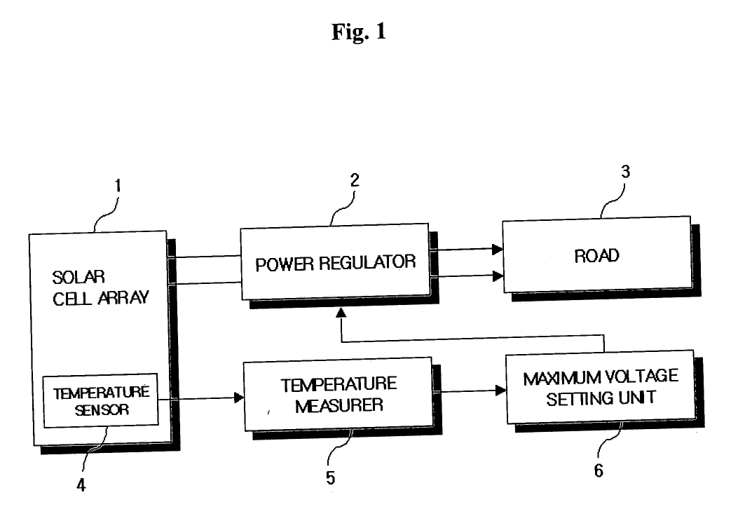

### DETAILED DESCRIPTION OF THE INVENTION

Reference will now be made in detail to the preferred embodiments of the present invention, examples of which are illustrated in the accompanying drawings.

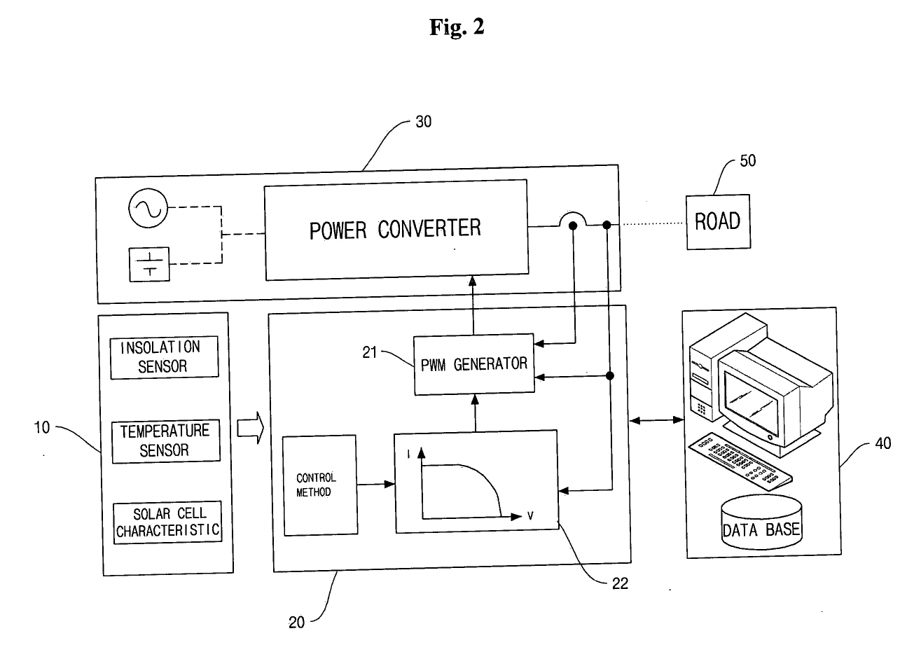

FIG. 2 illustrates the construction of a system for implementing a virtual solar cell according to the present invention. Referring to FIG. 2, the system for implementing a virtual solar cell includes a data detector 10, a controller 20, a power converter 30, a data logging unit, and a load 50. The data detector 10 has various measurement sensors including an insolation sensor for detecting the insolation of an area where a solar power generation system is located, a temperature sensor for detecting the temperature according to solar radiation and a wind velocity sensor for measuring wind velocity, and a solar battery unit cell. The data detector transmits data of each measurement sensor and the output characteristic of a solar cell to the controller 10 or data logging unit 40 through a wired or wireless communication method. Here, the data detector needs not have all of the sensors and solar battery unit cell but it may selectively include them.

The controller 20 controls the overall operation of the system, collects and classifies the data transmitted from the data detector 10, and stores the data in a database. In addition, the controller 20 designates an output condition on the basis of data received from the data detector or data previously stored in the database. The controller collects data from the data detector 10 or data logging unit 40 through a wired or wireless communication, as described above. The controller stores the data in such a manner that it classifies collected real-time information or calculated results (output condition and so on) by time, space or solar cell manufacturers and stores them.

Designation of the output condition means decision of a variety of conditions. For instance, it is determined whether real-time data or data stored in the database is used and whether the output characteristic of a solar call based on surrounding environments is produced using data actually inputted from the data detector 10 or data provided by a manufacturer.

Furthermore, controller 20 creates a voltage-current model for controlling the power converter 30 such that the system of the invention generates output having the same effect as that of an actual solar cell array. That is, the controller correctly models the output characteristic of the solar cell in accordance with external environments, which varies in real time, because the output characteristic of the solar cell varies with temperature, insolation and so on. The controller controls output voltage or current based on the modeling result.

The controller 20 includes a pulse width modulator 21 that generates a pulse width modulation signal such that the power converter 30 can follow the voltage-current model. While the controller can be configured of a microprocessor or PC, it is preferable to use a processor such as a digital signal processor for the controller for the purpose of high-speed data processing. In addition, the controller 20 exchanges required information with the date detector 10 or data logging unit 40 through a wired or wireless communication method.

The power converter 30 outputs output power having the same effect as the input/output characteristic of an actual solar cell to the load 50 in response to the pulse width modulation signal received from the pulse width modulator of the controller 20 using a power conversion device having AC or DC input power. Accordingly, the system for implementing a virtual solar cell of the present invention can obtain the same output effect as that of an actual solar cell system.

The data logging unit 40 that consists of a computer and a database receives real-time data from the data detector 10 through the controller 20 or accepts data processed or calculated by the controller to store it. If required, the data logging unit has a function of inputting data and a function of monitoring input/output data.

In other words, the data logging unit 40 includes a computer capable of interfacing with a user to store the output characteristic of a solar cell, temperature, insolation and wind velocity data transmitted from the controller 20 or data detector 10 in real time, and continuously updates them. Furthermore, the data logging unit 40 receives a command or data from the user or provides stored data to the user in real time.

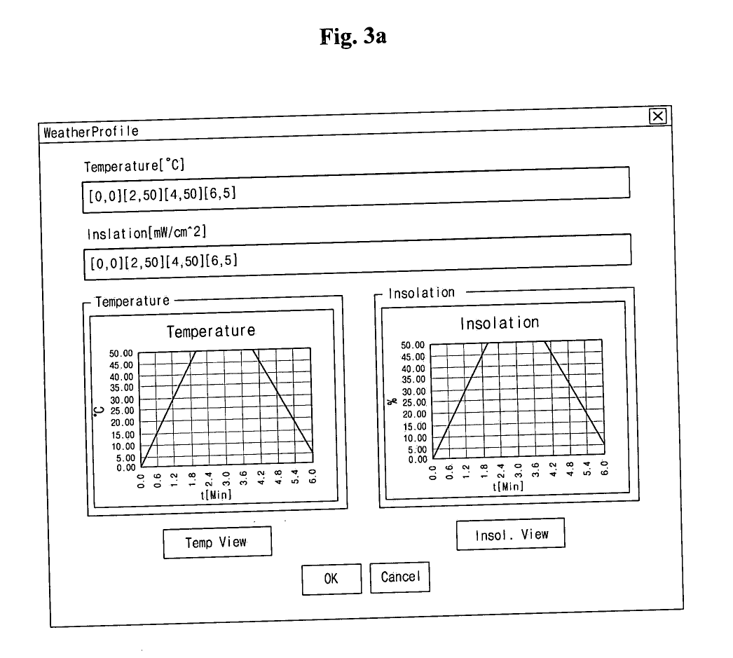

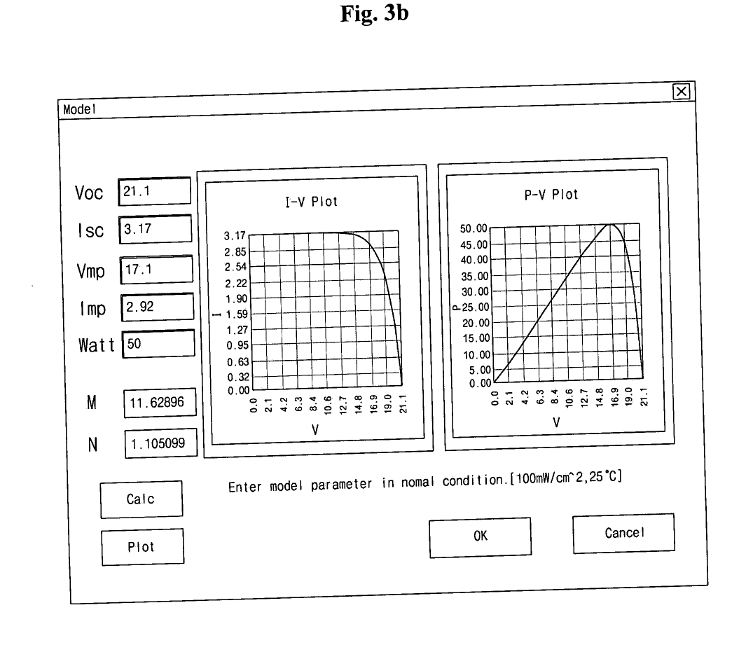

FIGS. 3a and 3b illustrate the composition of pictures showing an embodiment of generating a voltage-current model of a solar cell. As shown in FIGS. 3a and 3b, the present invention can create a voltage-current model through a user interface. FIG. 3a illustrates an embodiment of the composition of a picture through which temperature and insolation can in inputted. The picture can displays a temperature profile and insolation profile constructed on the basis of inputted data. FIG. 3b shows an embodiment of the composition of a picture through which voltage, current and power can be inputted and which can display a voltage-current plot and voltage-power plot based on inputted data.

The present invention can generate the voltage-current model in various manners. When a temperature and insolation are inputted (in real time or by a user), for example, the system of the present invention extracts the output characteristic of a solar cell according to the inputted temperature and insolation with reference to data provided by the solar cell manufacturer, to construct the voltage-current model. Otherwise, the system can input voltage and current parameters as well as the temperature and insolation to construct the model. Accordingly, the system according to the present invention can produce and monitor the output characteristic of the solar cell based on its environment any time any place only if there is external environment data of time and place a user wants.

Although the user interface screen is configured by the data logging unit 40 in the above-described embodiment, they can be constructed by the controller 20 to input a command and monitor a corresponding result. If the pictures are constructed by the data logging unit 40, input data is transmitted to the controller 20 through communication and the controller 20 generates a voltage-current model based on the transmitted data and, if required, sends the data to the data logging unit 40 for monitoring.

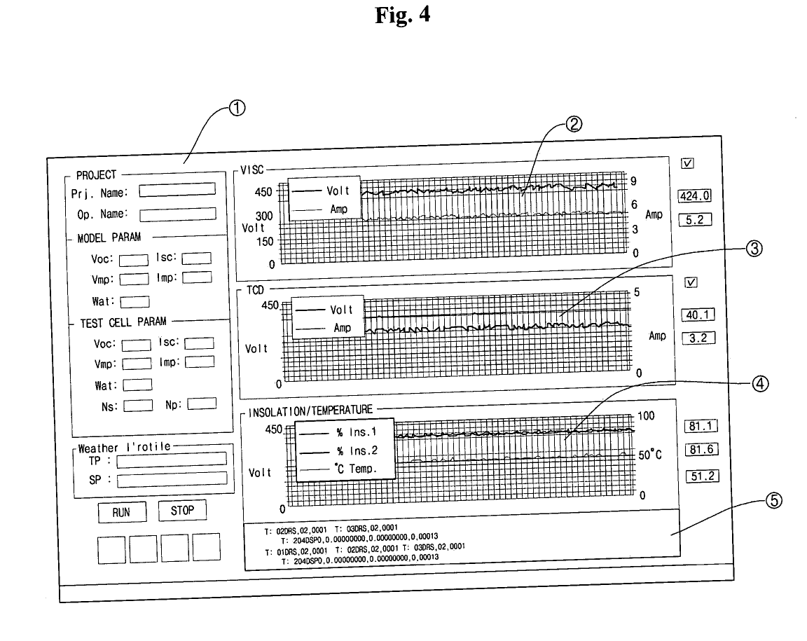

FIG. 4 shows the composition of a picture of the data logging unit 40 that stores and outputs information about various collected surrounding environments for producing the output characteristic of a solar cell. Referring to FIG. 4, the output picture of the data logging unit 40 logs collected information according to model parameters, solar cell's characteristic parameters classified based on an arbitrary condition and environment state such as weather information to display it.

In FIG. 4, \mathring{1} means a reference parameter and data name, which represents specification of a solar cell to be simulated and a project name having its data. \mathring{2} indicates the output power of the system and monitors voltage and current currently being outputted from the system. In addition, \mathring{3} represents voltage/current reference, which can monitor reference voltage and current of the system. \mathring{4} indicates insolation and temperature profiles and monitors a variation in insolation and temperature. Furthermore, \mathring{5} denotes a current communication connections stage of the data detector 10 and micro-controller 20.

As described above, the present invention can produce a virtual solar cell having the same electrical characteristic as that of the output of an actual solar cell according to environments such as insolation, temperature and so on through the aforementioned components without having an actual solar cell array. Moreover, the present invention can repeatedly execute an experiment about input/output characteristics of a solar cell under the same condition irrespective of a variation in surrounding environments.

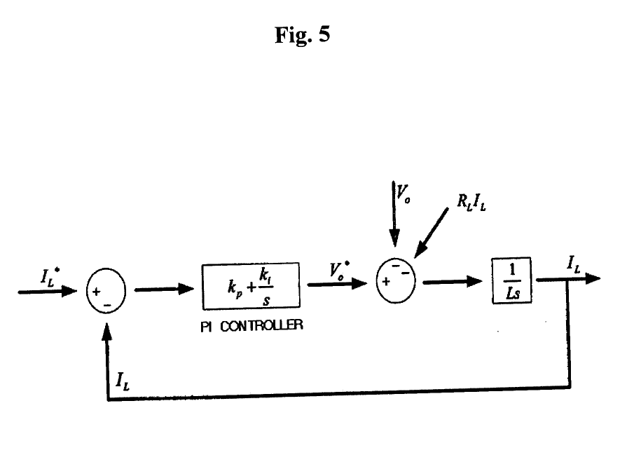

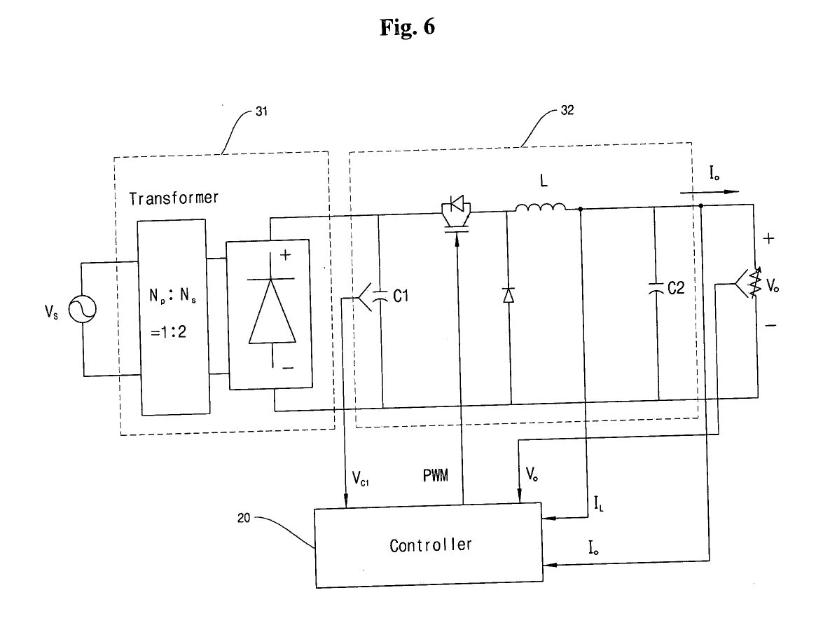

FIG. 5 is a circuit diagram of the power converter 30 according to the present invention, and FIG. 6 is a block diagram showing a current control principle of the controller 20.

As shown in FIG. 6, the power converter 30 includes an AC/DC rectifier 31 for boosting commercial 220V (AC) to rectify it, and a DC/DC converter (Buck converter) 32 for producing characteristic of a solar cell.

The present invention employs a single current control method not a voltage-current double loop control method as a current control technique because, when the system of the present invention and a system (not shown) connected with the system of the present invention perform the same voltage control, the control becomes difficult due to collision of voltage sources of the two systems. In the case that there is no possibility of generation of the above problem, however, any control method can be employed.

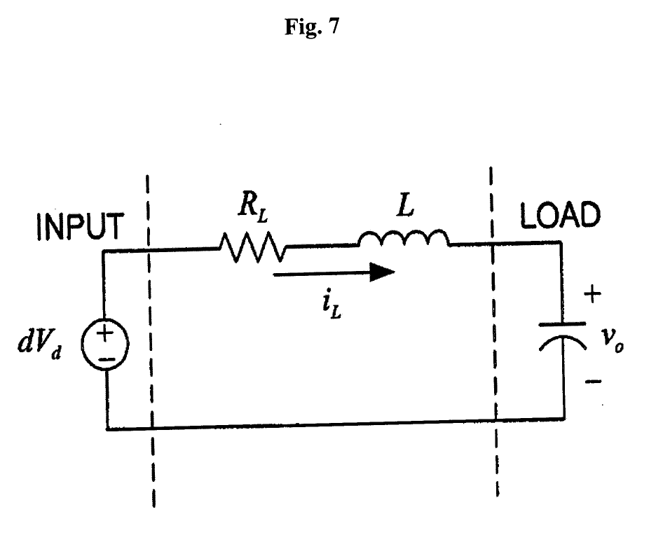

A design for the current controller is explained below in more detail. In designing of the current controller, first of all, it is assumed that output terminal voltage is maintained uniform during the transient period of current and a reactor resistance RL of the output terminal does not affect a time constant. Under this assumption, the equivalent circuit of FIG. 7 is represented as the following Equation 1.

$$L \frac{ⅆ {i}_{L}}{ⅆ t} = ⅆ {V}_{d} - {ν}_{0} - {R}_{L} {i}_{L} \qquad [ Equation 1 ]$$

Since it is assumed that input voltage dV_{d} is ideally modulated, a reference voltage signal is represented by the following Equation.
V_{d}*=dV_{d}=k_{P}(i_{L}*−i_{L})+∫kᵢ(i_{L}* −i_{L})+ν₀ [Equation 2]

When Equation 1 is replaced by the Equation 2 and Laplacion-transformed, a transfer function of the voltage-current controller 22 is obtained as follows.

$${G}_{i} ( s ) = \frac{{I}_{L}}{{I}_{L}^{*}} = \frac{{sk}_{p} + {k}_{i}}{{Ls}^{2} + ( {k}_{p} - {R}_{L} ) s + {k}_{i}} \qquad [ Equation 3 ]$$

Here, zero point is eliminated and a controller gain is obtained according to a pole assignment method that is a prototype second order system designing technique according to poles as follows.
kₚ=2ζᵢωₙᵢL+R_{L} [Equation 4]
kᵢ=ω²ₙᵢL [Equation 5]

Here, ωᵢ is the current damping ratio of the voltage-current controller 22 and ζₙᵢ is the intrinsic ratio damping frequency. The gain obtained through Equations 4 and 5 is not the optimum value because the system is not the prototype second order system. Accordingly, the bandwidth of the controller must be analytically found from the specification of the system.

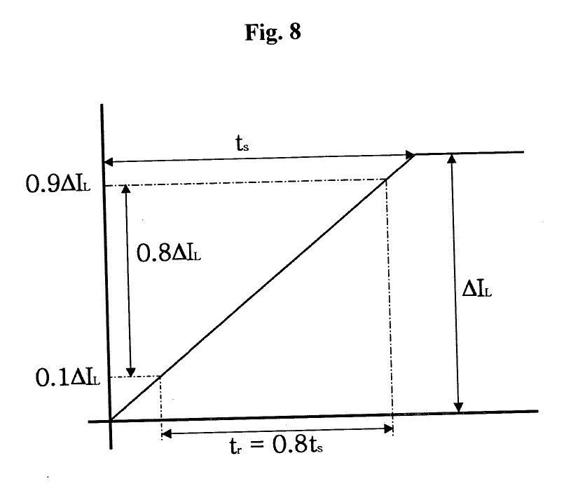

The current of the reactor of the equivalent circuit of FIG. 7 is controlled according to input voltage dV_{d} and output voltage Vₒ. FIG. 8 shows an over-current profile of the reactor output terminal. Rising time when current increases as shown in FIG. 8 is obtained as follows.

$${t}_{r} \geq 0.8 \frac{L Δ {I}_{L}}{{V}_{d} - {V}_{o}} \qquad [ Equation 6 ]$$

Here, tᵣ means rising time, ΔI_{L} represents over-current flowing through the reactor output terminal, V_{d} indicates the maximum-value of input voltage, and Vₒ means the maximum value of rated output. In FIG. 8, tₛ denotes settling time.

If the zero point of the voltage-current controller 22 is located much far from the starting point, the system is approximated to the prototype second order system and the intrinsic ration damping frequency ζₙᵢ is obtained from the rising time tᵣ of Equation 8 as follows.

$${ω}_{ni} = \frac{1 - 0.4167 {ζ}_{i} + 2.917 {ζ}_{i}^{2}}{{t}_{r}} \qquad [ Equation 7 ]$$

Therefore, the intrinsic ration damping frequency ζₙᵢ is controlled based on the damping ratio ωᵢ of the voltage-current controller 22 according to pole assignment design so that the rising time and bandwidth can be controlled.

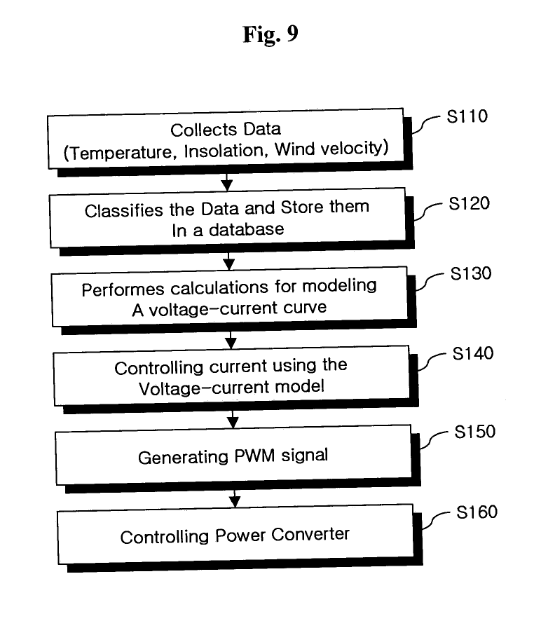

The operation procedure of the system according to the present invention having the aforementioned construction is explained below with reference to FIG. 9.

The system of the present invention can produce a virtual solar cell in two modes. The first mode produces a virtual solar cell on the basis of the database of actually measured temperatures, insolations and manufacturers. In this case, insolation and temperature data detected by the data detector 10 and specification of a module provided by a solar cell manufacturer are used as basic data. The second mode produces a virtual solar cell using an arbitrary value a user desires as data. In this case, temperature, insolation, and voltage, current, open voltage and short-circuit current at the maximum power point can be inputted through a user interface.

The operation procedure of the system of the present invention is described below in consideration of characteristics of the two modes.

First of all, the data detector 10 collects data for realizing the output characteristic of a solar cell in real time using sensors for sensing temperature, insolation and wind velocity, at step S110. The controller 20 transmits the real-time data collected by the data detector 10 to the data logging unit 40. The data logging unit 40 classifies the real-time data transmitted from the controller 20 by time, place and solar cell manufacturer and systematically stores them in a database, at step S120. The data logging unit 40 provides environment information stored in the database to the controller 20 at appropriate time required by a user.

Then, the controller 20 performs calculations for modeling a voltage-current curve the most suitable for an actual product using a control algorithm on the basis of the real-time data including temperature, insolation and wind velocity and characteristic data of solar cells classified by manufacturers, at step S130.

Subsequently, the current controller carries out current control using the voltage-current model as a reference value according to a predetermined control method, at step S140. The pulse width modulator 21 outputs a pulse width modulation signal to the power converter 30 according to the output value of the current controller.

Then, the power converter 30 provides power for producing the same output characteristic as that of an actual solar cell to the load 50 in response to the pulse width modulation signal applied from the pulse width modulator 21 using a predetermined power conversion method. Accordingly, it is possible to collect real-time output of the solar cell according to the temperature, insolation and wind velocity and output characteristics of solar cells by manufacturers, generated under arbitrary weather conditions according to a user's request.

Here, the user can remotely control and monitor the operation of the controller 20 through the computer included in the data logging unit 40 and set the environment of a desired condition to designate an output characteristic condition of a solar cell. For this, the data logging unit 40 includes auto/manual modes to set a user's operation range efficiently.

The present invention has the following advantages. Firstly, the present invention models a voltage-current model according to environmental conditions to produce a virtual solar cell that replaces an actual solar cell. This can reproduce an experimental environment having the same insolation and temperature as those of an actual solar cell array according to conditions set by a user. Accordingly, productivity and reliability in research and development in solar cells can be remarkably improved.

Secondly, the present invention can minimize the size of a solar cell system and eliminates limitations in places where solar cells are installed. This improves convenience of experiments and researches and reduces a period of time required for development. In addition, the system of the present invention can be used for obtaining objective estimation of research results.

Thirdly, temperature and insolation information and previous data about output characteristics of solar cells, stored in the database, can be reproduced to perform repeated experiments under a condition having the same temperature and insulation without varying output characteristic according to a variation in weather.

1. A system for implementing a virtual solar cell, comprising:
a data detector including a measurement sensor and adapted to collect external environment data;
a controller for receiving real-time data from the data detector, classifying the received data in a predetermined format to transmit the classified data to a data logging unit, generating a voltage-current model having the same effect as that of an actual solar cell on the basis of the received data, and generating a pulse width modulation signal for controlling a power converter according to the model;
the power converter for converting input power in response to the pulse width modulation signal to provide power to a load; and
the data logging unit for communicating with the controller or the data detector according to a predetermined communication method, and storing data received from the controller or the data detector.

2. The system for implementing a virtual solar cell as claimed in claim 1, wherein the data detector further includes a unit cell solar battery.

3. The system for implementing a virtual solar cell as claimed in claim 1, wherein the measurement sensor includes at least one of a temperature sensor, insolation sensor or wind velocity sensor.

4. The system for implementing a virtual solar cell as claimed in claim 1, wherein the data logging unit classifies data by time, place and solar cell manufacturers to store the data.

5. The system for implementing a virtual solar cell as claimed in claim 1, wherein the controller generates the voltage-current model on the basis of the real-time data received from the data detector or previously stored data received from the data logging unit.

6. A method for implementing a virtual solar cell, comprising:
allowing a controller to receive data from the outside;
classifying the received data in a predetermined format or stores it;
generating a voltage-current model for obtaining output characteristic of an actual solar cell on the basis of the received data;
performing current control according to the generated model;
generating a pulse width modulation signal according to a result of the current control; and
controlling a power converter in response to the pulse width modulation signal.

7. The method for implementing a virtual solar cell as claimed in claim 6, wherein the data received by the controller includes at least one of temperature data, insolation data and output characteristic data of a unit solar cell.

8. The method for implementing a virtual solar cell as claimed in claim 6, wherein, in the step of classifying or storing the data, the data is classified by at least one of time, place and solar cell manufacturer and stored.

9. The method for implementing a virtual solar cell as claimed in claim 6, wherein in the step of generating the voltage-current model, the controller generates the voltage-current model on the basis of real-time data received from a data detector or arbitrary data inputted by a user through a predetermined method.

10. The method for implementing a virtual solar cell as claimed in claim 9, wherein the predetermined method is a method of inputting data through a user interface screen.
